(19) United States
(12) Patent Application Publication
(10) Pub. No.: US 2007/0141735 A1
(43) Pub. Date: Jun. 21, 2007

(54) METHOD OF MONITORING DEPOSITION TEMPERATURE OF A COPPER SEED LAYER AND METHOD OF FORMING A COPPER LAYER

(76) Inventors: Sung-Joong Joo, Seoul (KR); Han-Choon Lee, Seoul (KR)

Correspondence Address: SHERR & NOURSE, PLLC, 620 HERNDON PARKWAY, SUITE 200, HERNDON, VA, 20170, US

(21) Appl. No.: 11/610,783

(22) Filed: Dec. 14, 2006

(30) Foreign Application Priority Data
Dec. 19, 2005 (KR) 10-2005-0125635

(51) Int. Cl. H01L 21/66

(52) U.S. Cl. 438/17; 257/E21.579

(57) ABSTRACT

A method for monitoring a deposition temperature of a Cu seed layer by measuring an optical reflectivity of the Cu seed layer deposited on a substrate; and estimating the deposition temperature of the Cu seed layer by comparing the measured optical reflectivity with a reference optical reflectivity of a reference Cu seed layer in which an agglomeration phenomenon has not happened. The estimating step includes computing the deposition temperature of the Cu seed layer at a temperature higher than about −25° C. which is a reference deposition temperature for depositing the reference Cu seed layer if the measured reflectivity is smaller than the reference optical reflectivity.

The present application claims priority under 35 U.S.C. 119 and 35 U.S.C. 365 to Korean Patent Application No. 10-2005-0125635 (filed on Dec. 19, 2005), which is hereby incorporated by reference in its entirety.

### BACKGROUND

As semiconductor devices have trended towards larger scale integration and higher speed operation, methods of forming metal wiring using copper (Cu) layers have been proposed. Specifically, logic devices using 130 nm or smaller design rules have used a Cu damascene process for implementing interconnection wirings.

The procedure for forming a Cu layer for a wiring structure includes the steps of first forming a Cu seed layer and then electroplating a relatively thick Cu layer over the Cu seed layer. A damascene process has been introduced for Cu layer wirings, wherein the Cu layer is formed to fill via holes and/or trenches, and a chemical mechanical polishing (CMP) process is performed to planarize the Cu layer.

However, if the Cu seed layer is deposited at the room temperature, a Cu agglomeration phenomenon may occur. When it does, it is difficult to form the Cu seed layer having a good film quality and without discontinuities or variations in the thickness of the layer. Furthermore, it is difficult to electroplate the additional Cu layer on the Cu seed layer deteriorated by the agglomeration phenomenon.

In order to overcome this agglomeration phenomenon, the procedure for depositing the Cu seed layer may be performed at a temperature, e.g., about −25° C., which is lower than room temperature. To do this, when the Cu seed layer is formed, the wafer or substrate is mounted on a super low temperature electrostatic chuck (ESC) to lower the temperature of the wafer or substrate to about −25° C.

The processing chamber for depositing the Cu seed layer and the super low temperature ESC should be subject to a periodic maintenance (PM) procedure. The Cu target for the Cu seed layer should be also exchanged at regular intervals. After the PM procedure is performed or the target is exchanged, the temperature of the super lower temperature ESC or the substrate should be confirmed.

However, such a temperature confirmation procedure may be a very troublesome and difficult task, and it does not directly confirm whether or not the agglomeration phenomenon happens in the Cu seed layer deposited on the substrate. Accordingly, a monitoring method capable of directly confirming whether or not the agglomeration phenomenon has happened in the Cu seed layer and a method for forming the Cu layer more uniformly by using the same have been needed.

### SUMMARY

Embodiments relate to a method capable of directly monitoring a deposition temperature of a Cu seed layer based on whether or not the agglomeration phenomenon has happened and a method for forming the Cu layer more uniformly by using the same.

Embodiments relate to a method of monitoring a deposition temperature of a Cu seed layer. A method may include at least one of the following steps: measuring an optical reflectivity of the Cu seed layer deposited on a substrate; and/or estimating the deposition temperature of the Cu seed layer by comparing the measured optical reflectivity with a reference optical reflectivity of a reference Cu seed layer (in which an agglomeration phenomenon has not happened).

### BRIEF DESCRIPTION OF THE DRAWINGS

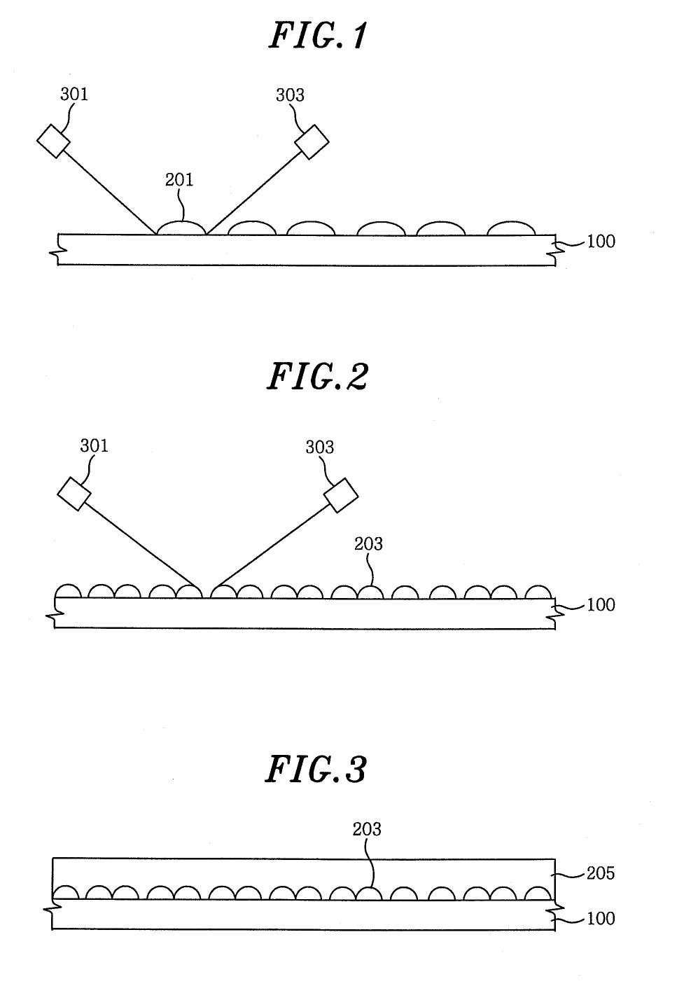

Example FIGS. 1 and 2 are schematic views describing a method for monitoring a deposition temperature of a Cu seed layer, in accordance with embodiments.

Example FIG. 3 provides a schematic cross sectional view describing a method for forming a Cu layer, in accordance with embodiments.

### DETAILED DESCRIPTION

Embodiments relate to a method capable of monitoring a deposition temperature of a Copper (Cu) seed layer based on an optical reflectivity of the Cu seed layer. Embodiments relate to a method forming a Cu layer.

In accordance with embodiments, after a Cu seed layer is deposited, a reflectivity of the Cu seed layer is measured so that it may be confirmed whether or not an agglomeration phenomenon has happened in the Cu seed layer based on the measured reflectivity, thereby providing a method for monitoring a deposition temperature of the Cu seed layer. This method of monitoring the deposition temperature of the Cu seed layer also prevents the subsequently electroplated Cu layer from being deteriorated due to the agglomeration phenomenon of the Cu seed layer.

Referring to FIGS. 1 and 2, a substrate 100 is mounted in a Cu seed layer deposition apparatus. A first Cu seed layer 201 or a second Cu seed layer 203 may be deposited on the substrate 100. The deposition apparatus has a processing chamber (not shown) in which a super low temperature electrostatic chuck (not shown) capable of maintaining the temperature of the substrate 100 at about −25° C. may be provided. However, one of ordinary skill in the art may appreciate that other temperatures may be sufficient to prevent Cu agglomeration under varying physical conditions present in differing deposition processes. A Cu target (not shown) for depositing the Cu seed layer 201 or 203 may be also provided.

A procedure for confirming whether or not an initial deposition procedure is being properly performed may be used after a periodic maintenance (PM) procedure is performed or the target is exchanged. At this point, it should be confirmed whether or not an agglomeration phenomenon has happened in the Cu seed layer 201 or 203 as shown in FIGS. 1 or 2. Such a confirmation procedure is performed by measuring a reflectivity of the deposited Cu layer 201 or 203.

If the Cu agglomeration phenomenon has reached a relatively high level as a case of the first Cu seed layer 201 shown in FIG. 1, the reflectivity of the first Cu seed layer to be measured by a reflectivity measuring apparatus, which includes a light emitting unit 301 and a light receiving unit 303, may be a relatively low value, e.g., at a value of about 75.

In contrast, if the Cu agglomeration phenomenon stays at a relatively low level as illustrated in the second Cu seed layer 203 shown in FIG. 2, the reflectivity may be measured as a relatively high value, e.g., at a value of about 110.

Accordingly, if the reflectivity value obtained by measuring an optical reflectivity of the deposited Cu seed layer 201 or 203 is not smaller than a reference reflectivity value, e.g., at a value of about 110, from which it is determined that there is no substantial Cu agglomeration, an initial setup for the deposition apparatus may be determined to be completed.

If the measured reflectivity value is smaller than the reference reflectivity value, it may be considered that the deposition procedure for depositing the Cu seed layer is performed at a temperature higher than about −25° C. However, one of ordinary skill in the art may appreciate that other temperatures may be sufficient to prevent Cu agglomeration under varying physical conditions present in differing deposition processes. As a result, an initial setup for the deposition apparatus in which the periodic maintenance procedure has been performed or its target is exchanged should be finely readjusted. Specifically, the deposition temperature can be maintained at about −25° C. by controlling the temperature of the electrostatic chuck for supporting the substrate 100 to be lower.

If the optical reflectivity as shown in FIG. 2 is measured to be a specific value or more, e.g., at a value of about 110, which means that the agglomeration phenomenon is relatively low, an electroplating or other deposition process may be used to form a Cu layer 205 on the second Cu layer 203.

A procedure for measuring the agglomeration degree of the Cu seed layer 201 or 203, and an electroplating procedure for forming a Cu layer 205 on the second Cu seed layer 203 which is qualified to be well-deposited as described above may be applied to a process for employing a Cu layer as an interconnection wiring structure, e.g., the Cu damascene process or other deposition process. Also, a method for monitoring the deposition temperature by measuring the reflectivity of the Cu seed layer 201 or 203 may be applied to the initial setup for the deposition apparatus for depositing the Cu seed layer after the periodic maintenance procedure is performed or the target used in the deposition apparatus is exchanged.

In accordance with embodiments, it is possible to reduce the time required for the temperature calibration after the periodic maintenance procedure for the Cu seed layer deposition apparatus is performed or the target is exchanged. In embodiments, the deposition temperature of Cu seed layers may be periodically measured more easily. In embodiments, the agglomeration phenomenon may be substantially prevented so that the electroplating or other deposition process may be used to grow the Cu layer on a substantially uniformly deposited Cu seed layer.

It will be obvious and apparent to those skilled in the art that various modifications and variations can be made in the embodiments disclosed. Thus, it is intended that the disclosed embodiments covers the obvious and apparent modifications and variations, provided that they are within the scope of the appended claims and their equivalents.

What is claimed is:

1. A method comprising:
measuring an optical reflectivity of a Copper seed layer to determine a measured optical reflectivity; and
estimating a deposition temperature of the Copper seed layer from the measured optical reflectivity.

2. The method of claim 1, wherein the Copper seed layer is deposited over a substrate.

3. The method of claim 1, wherein said estimating the deposition temperature of the Copper seed layer comprises comparing the measured optical reflectivity with a reference optical reflectivity.

4. The method of claim 3, wherein the reference optical reflectivity is from a reference Copper seed layer.

5. The method of claim 4, wherein an agglomeration phenomenon has not occurred in the reference Copper seed layer.

6. The method of claim 3, wherein said estimating the deposition temperature of the Copper seed layer comprises determining that the deposition temperature of the Cu seed layer is higher than about −25° C. if the measured optical reflectivity is less than the reference optical reflectivity.

7. The method of claim 6, wherein the reference optical reflectivity is between about 75 and about 110.

8. The method of claim 7, wherein the reference optical reflectivity is about 75.

9. The method of claim 7, wherein the reference optical reflectivity is about 110.

10. The method of claim 6, wherein said estimating the deposition temperature of the Cu seed layer comprises determining that an agglomeration phenomenon has occurred in the Copper seed layer if the measured reflectivity is less than the reference optical reflectivity.

11. A method according to claim 1, comprising forming a Copper layer over the Copper seed layer.

12. The method of claim 11, comprising determining if the deposition temperature of the Copper seed layer is less than a reference deposition temperature.

13. The method of claim 12, wherein if the deposition temperature of the Copper seed layer is less than the reference deposition temperature, then forming the Copper layer over the Copper seed layer.

14. The method of claim 11, wherein the Copper layer is formed by electroplating.

15. The method of claim 12, wherein said determining if the deposition temperature of the Copper seed layer is less than a reference deposition temperature comprises determining if an agglomeration phenomenon has occurred in the Copper seed layer.

16. The method of claim 15, wherein said determining if is the agglomeration phenomenon has occurred in the Copper seed layer comprises estimating if the deposition temperature of the Copper seed layer is less than about −25° C.

17. The method of claim 16, wherein said estimating if the deposition temperature of the Copper seed layer is less than about −25° C. comprises determining if the measured optical reflectivity is higher than a reference optical reflectivity.
